(19) United States
(12) Patent Application Publication
(10) Pub. No.: US 2019/0105991 A1
(43) Pub. Date: Apr. 11, 2019

(54) SOLAR EXTENDED RANGE ELECTRIC VEHICLE

(71) Applicant: DIVERGENT TECHNOLOGIES, INC., Los Angeles, CA (US)

(72) Inventors: John Russell BUCKNELL, El Segundo, CA (US); Stuart Paul MACEY, Laguna Niguel, CA (US); Broc William TenHOUTEN, Rancho Palos Verdes, CA (US); David Charles O'CONNELL, Huntington Beach, CA (US)

(21) Appl. No.: 15/730,666

(22) Filed: Oct. 11, 2017

(51) Int. Cl. B60L 8/00; B60L 11/18; H01L 31/042; H02S 10/40

(52) U.S. Cl. CPC B60L 8/003; B60L 11/18; B60K 2016/003; H02S 10/40; H01L 31/042

(57) ABSTRACT

A solar extended range electric vehicle, various structures and assemblies within the vehicle, and additive manufacturing techniques for these structure and assemblies are disclosed. In an aspect of the present disclosure, a solar extended-range vehicle includes a frame coupled to an exterior structure, a suspension system mounted to the exterior structure and coupled to a wheel system, at least one electric motor coupled to the wheel system, and at least one stowable solar panel arranged along a region of the frame for supplying power to the electric motor.

### BACKGROUND

### Field

The present disclosure relates generally to transport structures, and more specifically to lightweight, aerodynamically-contoured vehicles that use solar panels for extending vehicle range.

### Background

Until recently, producers of automobiles and other transport structures were constrained to rely on the process of “machining” often heavy and dense metallic materials to produce essential vehicle components.

With the increased popularity of additive manufacturing (“AM”), also called 3-D printing, parts once created exclusively by machining and other subtractive processes may now be cost-effectively 3-D printed as metals, plastics, and sophisticated components using strong, lightweight composite materials such as carbon fiber. Using additive manufacturing, vehicle parts including the chassis and body panels can be more easily made using any number of lighter composite materials to produce an overall lighter, more sophisticated, more reliable and more streamlined vehicle having a larger number of features at lower costs.

In recognition of the advantages associated with the use of AM to complement conventional machining techniques in the automotive industry, a new line of vehicles has been proposed to exploit new technology arenas. One such arena involves the efficient use of solar energy in transportation. Conventional approaches to developing solar-powered cars have been circumscribed by practical limitations including, for example, the inability to harness adequate amounts of solar energy given the energy demands of conventional solar vehicles.

Attempts have been made to use solar power to augment, rather than replace, gas or electric driven systems, but here again, any benefit from the solar harnessing attempts has been cancelled out by the excessive mass and drag associated with the vehicle. Even for lighter vehicles, conventional approaches involve vehicles covered with large numbers of static solar panels mounted to the vehicle, where the capacity of the panels to receive energy is limited by the angle of solar rays. Moreover, each such solar panel on the static array contributes to the overall mass of the vehicle, and ultimately reduces any benefit of solar absorption.

The solar vehicle described hereinbelow, and the structures and assemblies that include it, represent a solution to these and other longstanding problems.

### SUMMARY

Several aspects of solar-powered extended range vehicles, structures and assemblies used in these vehicles, and techniques for additively manufacturing such structures and assemblies will be described more fully hereinafter with reference to various illustrative aspects of the present disclosure.

In one aspect of the present disclosure, a solar extended-range vehicle includes an aerodynamically-contoured frame coupled to an exterior structure, a suspension system mounted to the exterior structure and coupled to a wheel system, at least one electric motor coupled to the wheel system, and at least one stowable solar panel arranged along a region of the frame for supplying power to the electric motor.

In another aspect of the present disclosure, a solar extended range electric vehicle includes a frame coupled to an exterior structure, a suspension system mounted on the exterior structure, an impact structure arranged near a front of the frame and coupled to the suspension system, a wheel system coupled to the suspension system, a plurality of electric motors coupled to the wheel system, and at least one stowable solar panel operably coupled to a battery assembly.

Different solar-powered extended range vehicles, structures and assembly techniques may be described that have not previously been developed or proposed. It will be understood that other aspects of these vehicles, structures and techniques will become readily apparent to those skilled in the art based on the following detailed description, wherein they are shown and described in only several embodiments by way of illustration. As will be appreciated by those skilled in the art, these vehicles, structures and techniques can be realized with other embodiments without departing from the spirit and scope of the invention. Accordingly, the drawings and detailed description are to be regarded as illustrative in nature and not as restrictive.

### BRIEF DESCRIPTION OF THE DRAWINGS

Various solar-powered extended range vehicles, structures and assembly techniques will now be presented in the detailed description by way of example, and not by way of limitation, in the accompanying drawings, wherein:

FIG. 1 is a perspective view of a solar extended range electric vehicle.

FIG. 2A is a plan view of a solar extended range electric vehicle in mobile mode.

FIG. 2B is a perspective view of the solar extended range electric vehicle in mobile mode.

FIG. 2C is a front view of the solar extended range electric vehicle in mobile mode.

FIG. 2D is a side view of the solar extended range electric vehicle in mobile mode.

FIG. 3A is a plan view of a solar extended range electric vehicle in stationary mode.

FIG. 3B is a perspective view of the solar extended range electric vehicle in stationary mode.

FIG. 3C is a front view of a solar extended range electric vehicle in stationary mode.

FIG. 3D is a side view of a solar extended range electric vehicle in stationary mode.

FIG. 4A is a front perspective view of a solar extended range electric vehicle illustrating the deploying of its solar panels from a position integrated along the frame.

FIG. 4B is a rear perspective view of a solar extended range electric vehicle illustrating the deploying of its solar panels from a position integrated along the frame.

FIG. 5 is a plan view of a solar extended range electric vehicle showing a teardrop contour of the vehicle designed to reduce aerodynamic drag.

FIG. 6 is a side view showing an exemplary relative placement of passengers using inline seating in a solar extended range electric vehicle.

FIG. 7A is a conceptual elevation view of a solar extended range electric vehicle having deployable solar arrays.

FIG. 7B is a conceptual elevation view of solar extended range electric vehicle engaged in active tracking of solar radiation

FIG. 8 is a conceptual elevation view of the solar extended range electric vehicle optimizing its positioning of solar panels in the stationary position.

FIG. 9 is a conceptual side view of a solar extended range electric vehicle deploying an array of five panels coupled together by respective pivots extending across a surface of its frame.

FIG. 10A is a plan view of a canopy frame.

FIG. 10B is a plan view of an exterior structure and an impact structure.

FIG. 10C is a plan view of a vehicle frame and the exterior structure mounted in the frame and coupled to an impact structure.

FIG. 10D is a view from below of the underside of an exterior structure.

FIG. 11 is a perspective view of a composite tub for use in the space frame structure of the solar extended range electric vehicle.

FIG. 12 is a rear transparent view of the solar extended range electric vehicle in which an occupant is seated within the composite tub of FIG. 11.

FIG. 13 is a plan view of a solar extended range electric vehicle having solar panels arranged in an exemplary configuration along a front and a rear of the frame.

FIG. 14 is a side view of a solar extended range electric vehicle having solar panels arranged in another exemplary configuration along a rear of the frame.

FIG. 15 is a side view of a solar extended range electric vehicle having foldable solar panels arranged along a top surface of the frame in a foldable manner in another exemplary configuration.

### DETAILED DESCRIPTION

The detailed description set forth below in connection with the drawings is intended to provide a description of exemplary embodiments of solar-powered extended range vehicles, structures and assemblies used in these vehicles, and techniques for additively manufacturing such structures and assemblies. The description is not intended to represent the only embodiments in which the invention may be practiced. The term “exemplary” used throughout this disclosure means “serving as an example, instance, or illustration,” and should not necessarily be construed as preferred or advantageous over other embodiments presented in this disclosure. The detailed description includes specific details for the purpose of providing a thorough and complete disclosure that fully conveys the scope of the invention to those skilled in the art. However, the invention may be practiced without these specific details. In some instances, well-known structures and components may be shown in block diagram form, or omitted entirely, in order to avoid obscuring the various concepts presented throughout this disclosure.

Numerous types of AM exist. Most AM techniques involve creating a computer aided design (CAD) 3-D model of the part and use software to ‘slice’ the CAD model into a format having printer-readable instructions for building the part layer-by-layer (‘slice-by-slice’). The 3-D printer may be provided with the desired material(s) for use in 3-D printing the part pursuant to these instructions.

Depending on the printer technology such as powder bed fusion (PBF), in which PBF is a technology that itself incorporates various 3-D sub-classes of technology (including Selective Laser Melting (SLM), Selective Laser Sintering (SLS), Electron Beam Melting (EBM), Direct Metal Layer Sintering (DMLS), Selective Heat Sintering (SHS) and the like), the 3-D printer may include a powder bed for containing the powdered material from which the print material is sourced. The powdered material may be uniformly deposited layer-by-layer using a roller on a build plate. Armed with the 3-D printing instructions from the slicer operation, the controller circuit associated with the 3-D printer may illuminate a laser or electron beam onto a deflector. The deflector may cause the beam to focus on designated regions within that layer of deposited powder. The beam fuses or melts together the powder in the designated regions in the layer if so instructed by the slicer program, and ignores the remaining regions of powder in the layer. The 3-D printer repeats these tasks for designated regions in each deposited layer until the entire structure is rendered from the build plate up. Excess powder is collected from all the non-fused regions and the completed AM structure is removed from the printer, at which point the 3-D printer can be readied for reuse as desired.

In other AM techniques such as fused deposition modeling (FDM), the CAD file is used similarly and instructions are generated based on a sliced data model as before. However, in FDM, a material-injecting print extruder mounted to a gantry system is used in lieu of a laser or electron source. One or more reels of desired materials in filament form, typically a thermoplastic, is provided to the FDM printer. The filament is fed through a nozzle, heated up to condition it for printing, and extruded through the nozzle onto a region of the build plate dictated by the print software. That is, the FDM print extruder heats and extrudes the material onto selected regions associated with a layer and extrudes nothing at the remaining regions of the layer where nothing is to be printed. This practice is in contrast to PBF techniques, where powder is used to fill up the entire layer and then the desired regions of the layer are fused together. The FDM printer continues to perform this process layer-by-layer, until the structure is printed. Instead of actively being fused together by a laser or beam, the material in the FDM printer is configured to harden as it cools, either by itself or with an extruded adhesive. In both FDM and PBF techniques, if an area of overhang of the structure being printed (e.g., an upper portion of a hollow case) is subject to gravitational deformation or collapse prior to completion of the AM process, the 3-D printer may further print a section of “support material” which, while not necessarily part of the structure itself, serves to maintain the structural integrity of the thing being printed. After the combined structure dries and is removed from the 3-D printer, the support material may be carefully removed from the structural material using various techniques.

In one aspect of the present disclosure, a solar extended range electric vehicle is introduced. While the vehicle may itself have a plethora of styles and practical uses, the vehicle may in one exemplary embodiment be an all-weather commuting vehicle. The vehicle's range may also vary depending on a number of factors including mass, type and area to be driven, etc., the vehicle in one embodiment may be configured to have at least a 200-mile range on regulatory cycles, including an electrically charged engine and the solar range enhancement capabilities. Advantageously, in the embodiment shown, the vehicle need not compromise in other areas (e.g., features, comfort, performance or some combination thereof). More specifically, attributes such as comfort, stability, and impact protection properties of the vehicle may resemble those features of conventional passenger cars.

The 200-mile range may be made possible by the low demand energy of the vehicle, which can be less than 150 Watt hours per mile (W h/mi), and, as discussed below, by solar charging the battery, resulting in an extended range. Features that can enable both the low demand energy and the significant mileage provided by solar charging include, for example, the low mass of the vehicle, the low automotive coefficient of drag (Cd), and the low frontal area (A). These features may be achieved in one embodiment by (i) dual passenger inline seating which may result in an approximately 440 Kg curb mass, (ii) low frontal area and a high fineness ratio to achieve Cd. A (Coefficient of drag×area)=approximately 0.15 m², and (iii) the smallest battery possible in view of the vehicle range and power, with approximately 20 kWh usable.

The excellent dynamics of the vehicle in these embodiments may be achieved, for example, using a high power-to-weight ratio and a high overturning moment. These features, in turn, may be realized by the following exemplary attributes: (i) a power of 80+kW due to vehicle motors and power electronics, (ii) all-wheel drive (AWD) for maximum power utilization (battery limited), (iii) a low center of gravity (CG) as a result of a strategically low battery placement and low seat height (described further below), and (iv) a narrow but non-zero track width, dynamic leaning, and full torque vectoring via wheel motors. It will be appreciated in other embodiments, that other attributes may employed, however, and may provide an equally suitable performance.

These and other features of the solar extended range electric vehicle are described in more detail with reference to the illustrations and explanations that follow.

Energy Efficiency Analysis.

This section presents data from the top-down in an energy efficiency analysis that was performed to enable an optimal and non-compromising design of the solar extended range electric vehicle. One purpose of this analysis was to determine test mass and Cd·A values of the vehicle that would yield a desired energy demand value of less than the chosen target of 150 Wh/mi. Survey of published battery electric vehicle (BEV) performance has shown that drive cycle energy consumption is a function of three terms: (i) coefficient of drag×Area (Cd×A), (ii) rolling resistance (which is a function of the vehicle mass) and (iii) Inertia forces (which are also a function of mass). Inertia forces are largely recoverable with regeneration techniques.

In short, Radiometric analysis of modern BEVs suggests that a test mass of approximately 510 kg and a coefficient of drag×area of approximately 0.12 m² Cd×A should be targeted in the solar vehicle to achieve the desired energy output limit of <150 Wh/mi.

Solar Energy Analysis.

SA solar energy analysis was performed to determine the design and location of the solar panels on the solar energy range extended vehicle. Table I illustrates the result of that analysis:

TABLE 1
Solar Energy Analysis

| | | Continental | Los Angeles, | Los Angeles, | Boston, June, | Boston, | |
|---|---|---|---|---|---|---|---|
| | | US Annual | June, 8 hour | December, 8 | 8 hour work | December, 8 | |
| | | Mean | work day | hour work day | day | hour work day | Notes |
| Vehicle | Wh/mile | 150 | 150 | 150 | 150 | 150 | Average over Urban/ |
| Efficiency | | | | | | | Highway cycles |
| Solar | kWh/m\hat{ }2/day | 4.50 | 6.00 | 4.00 | 4.50 | 1.50 | Flat-Horizontal Panel |
| Insolation | | | | | | | w/o weather |
| Solar Cell | fraction | 0.3 | 0.3 | 0.3 | 0.3 | 0.3 | Efficiency of best |
| Efficiency | | | | | | | commerical cells |
| Array | fraction | 0.70 | 0.70 | 0.70 | 0.70 | 0.70 | 2-Axis Solar tracking |
| Effectiveness | | | | | | | is 1.3-1.8x |
| Specific Solar | kWh/m\hat{ }2/day | 0.95 | 1.26 | 0.84 | 0.95 | 0.45 | Insolation times efficiency |
| Energy | | | | | | | times effectiveness |
| Solar Area | m\hat{ }2 | 2.50 | 2.50 | 2.50 | 2.50 | 2.50 | Solar array area times |
| | | | | | | | effectiveness/panel |
| Energy/Day | kWh/day | 2.363 | 3.150 | 2.100 | 2.363 | 1.125 | Stored energy |
| Solar range/Day | miles/day | 15.8 | 21.0 | 14.0 | 15.8 | 7.5 | |

Solar energy conversion efficiency and vehicle energy demand will likely improve over time. It should be noted that, while values of almost 16 miles daily range based solely on solar power have been achieved, that value is expected to increase further based on the various teachings in this disclosure and other factors.

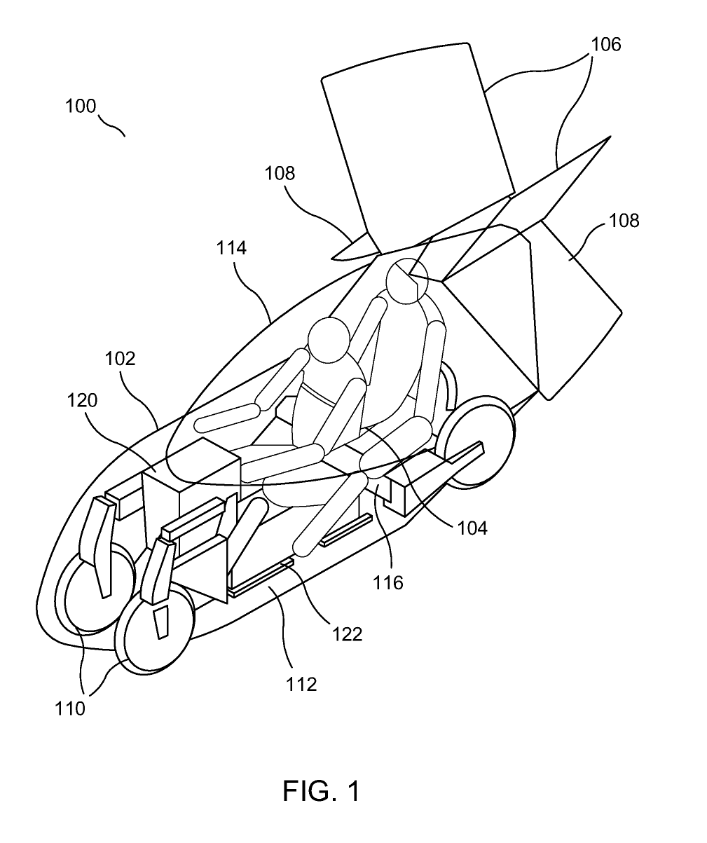

FIG. 1 is a perspective view of a solar extended range electric vehicle 100. The vehicle 100 may include an aerodynamically contoured frame 102, a transparent or semi-transparent canopy 114, an exterior structure 112, a suspension system 116 mounted to the exterior structure 112, center console 120, battery cells 122, and dual inline seating 104 to accommodate two occupants in this embodiment.

In addition, two solar panels 106 may be located on either side of the tail in a deployable array, which in this embodiment is a total area of three square meters. Solar panels 106 may provide sufficient energy for tasks like commuting and when folded or stowed to their original position, low drag. Additional solar panels 108 beneath primary array of solar panels 106 can provide additional energy when the sun is low in the sky with the vehicle oriented mostly along the North-South direction. Two-axis solar tracking can improve Array Effectiveness by a multiple in the range of 1.3-1.8.

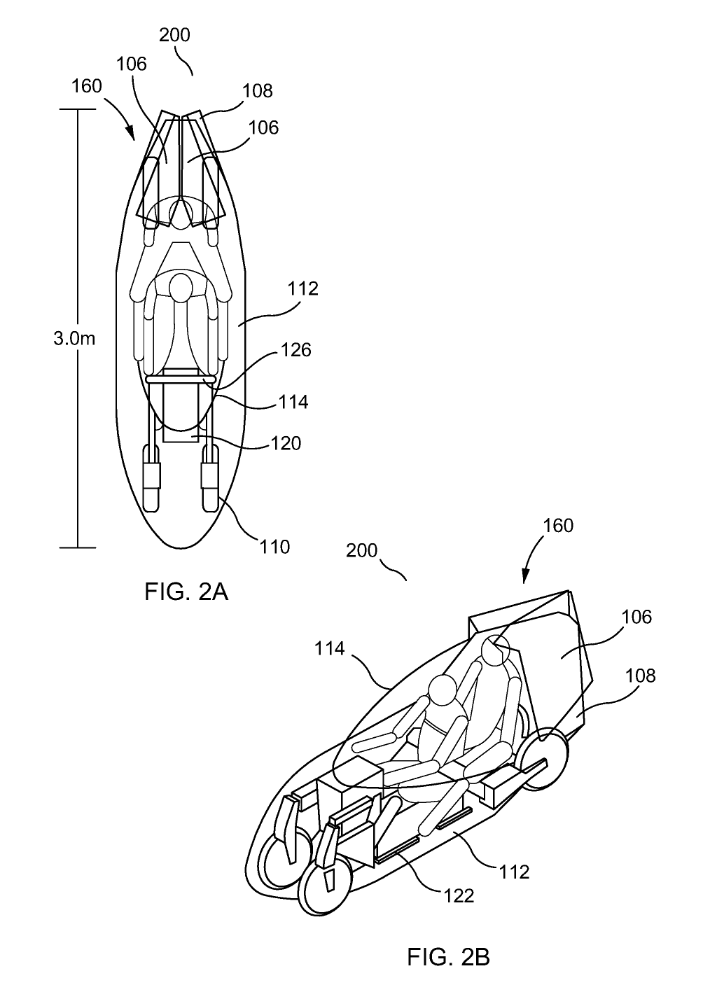

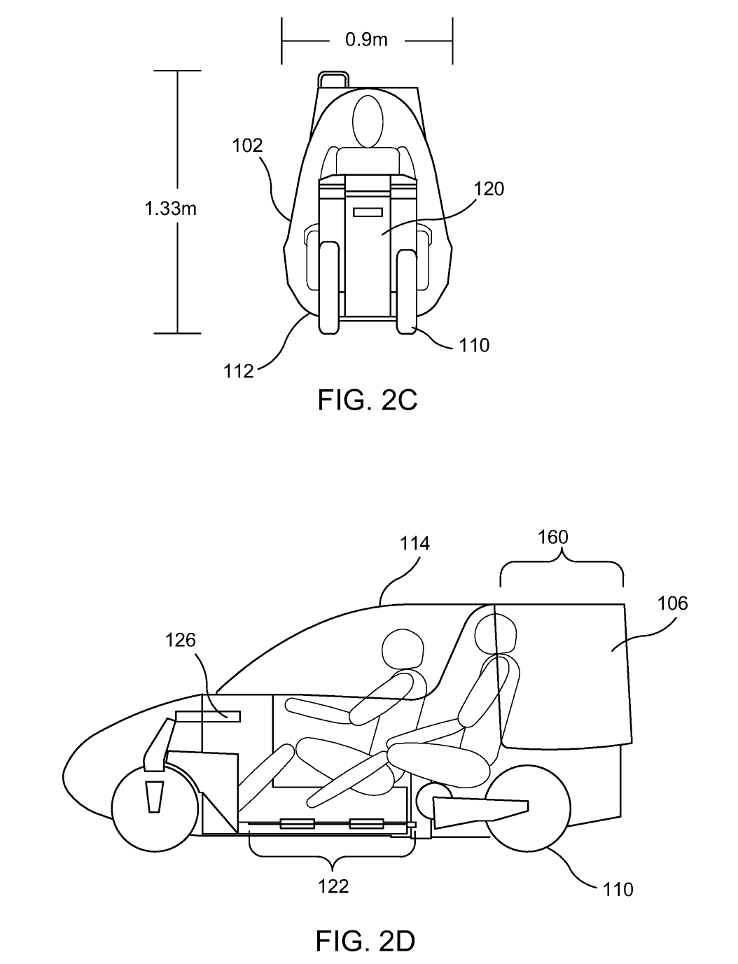

FIGS. 2A-D are respective plan, perspective, front and side views of a solar extended range electric vehicle 200 in mobile mode. As can be seen in FIGS. 2A and 2C, the vehicle 200 in this embodiment is 3.0 meters long, 1.33 meters high, and 0.9 meters wide. Particularly as shown if FIGS. 2A-B, the solar panels 106 and 108 are stowable by being foldable substantially flush against tail section 160 of the vehicle 200. Thus, to deactivate the solar panels and prepare for a more aerodynamically efficient mobile mode, lower solar panels 108 may first be folded downward flush along a frame 102 (FIG. 2C) of tail section 160. Thereupon, upper panels 108 may next be folded downward flush along upper panels 106. In this way, the amount of surface area and hence the drag decreases substantially, and the vehicle 200 is ready to be driven.

FIGS. 2A and 2D further shows the handlebar 126 steering mechanism as described in greater detail below. FIG. 2D shows a portion of prismatic battery cells 122 which are disposed under the passengers in this example. The passengers shown in FIG. 2A are in front of center console 120, which may include electronics for the various components and in other embodiments, some storage area, or a combination thereof. Circuits and wiring used in the motors, wheel system and/or suspension system may be included in the center console 120 in some embodiments. In other embodiments, center console 120 may house, or be proximate to, nested wheel motors in the front of the compartment. In certain embodiments, one of nose section or tail section 160 may include modest accommodations for storage (e.g., a few grocery bags). A suspension system 116 (FIG. 1) may be mounted to exterior structure 112 and coupled to wheel system 110.

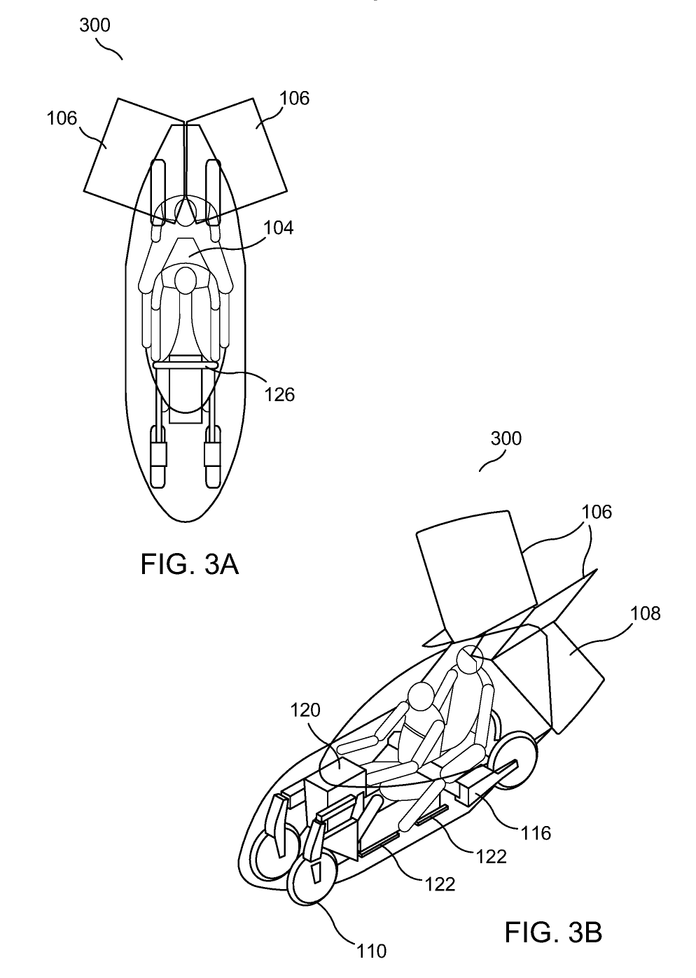

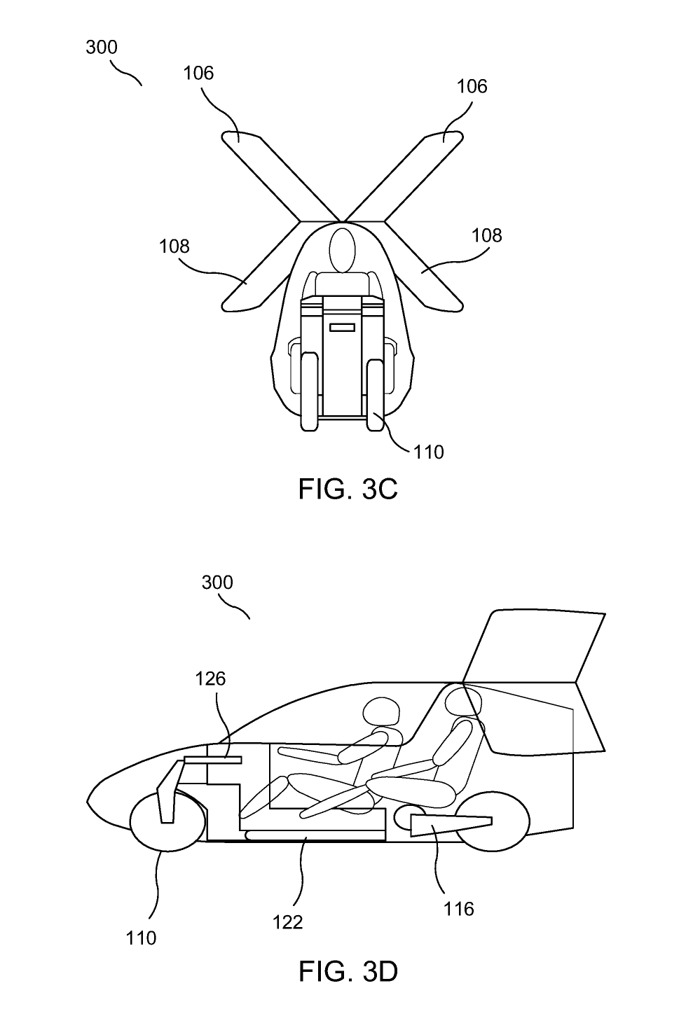

FIG. 3A-D are respective plan, perspective, front and side views of a solar extended range electric vehicle 300 in stationary mode. When the vehicle is stationary, such as when it is parked, it may be configured to absorb solar energy. The solar panels 106, 108 may be fully deployed. As shown in FIGS. 3A-D, the solar panels are deployed at different relative angles, enabling the panels to absorb sunlight in this configuration from one of four angles. Panels 108 may be configured to capture sunlight emitted lower on the horizon later in the day, whereas panels 106 may be more receptive to sunlight shining earlier in the day. The car may be in stationary mode anytime it is parked or otherwise not being driven. The drag introduced by the panels as deployed mean that it while it is generally undesirable in this embodiment to be mobile, other embodiments may impose a more aerodynamic design on the deployed panels, enabling the vehicle to move as it absorbs solar energy. In other embodiments where additional solar panels may be present on the vehicle that are flush and stationary, those additional panels may be receptive to absorbing sunlight while in the mobile mode. Further, while an array of four panels is shown in FIGS. 3A-D for purposes of illustration, other numbers of panels and other configurations are possible. Solar panels 106 or 108, or both, in another embodiment, may automatically be configured to adjust their position relative to the angle of the sun to receive maximum exposure. For example, a deployment motor may be associated with solar panels 106 and 108 that has as an input an intensity reading. In other embodiments, weather information, pictorially and/or audibly may be streamed to such a deployment motor for interpretation by a processing system. These types of predictive behavior events may substitute for or complement an input system that detects optimal radiation and radiation angles for use by solar panels 106 and 108 during the deployment mode. In these embodiments, care should be taken to ensure that solar absorption is occurring at a higher degree than use of energy due to solar tracking and other procedures, such that a net gain is likely to be significantly greater where the tracking methods or weather readings are used.

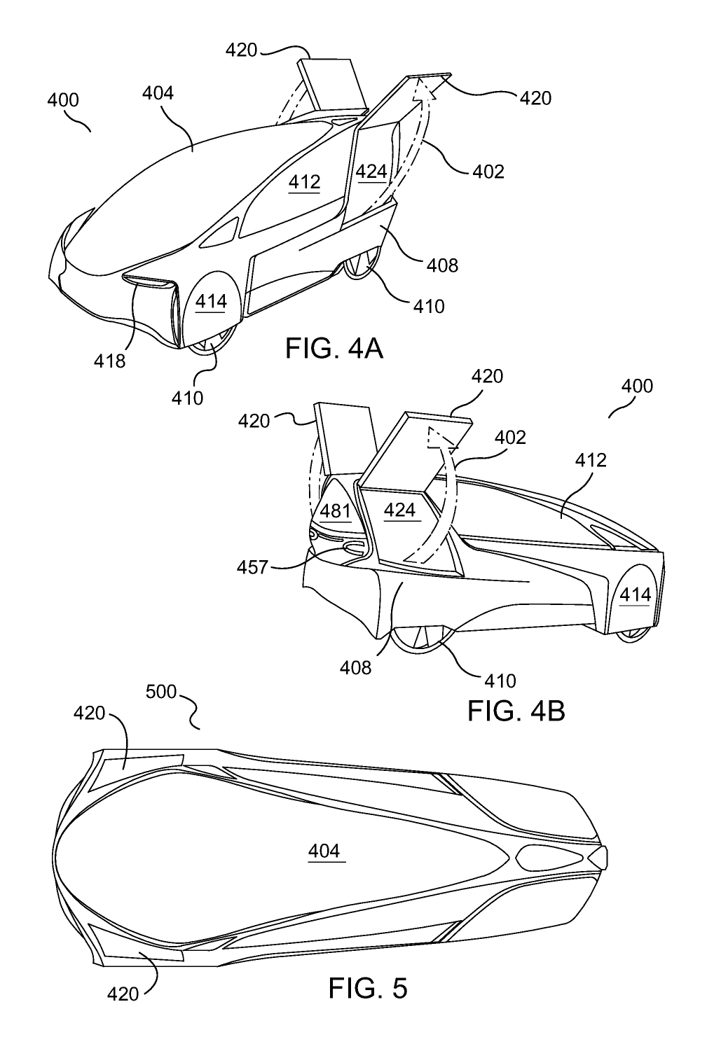

FIG. 4A is a front perspective view of a solar extended range electric vehicle 400 deploying its solar panels 420 from a position integrated along the frame. In this embodiment, solar panels 420 are integrated along frame 408 of the vehicle by means of pockets 424. Thus, initially before the vehicle 400 transitions to stationary mode, solar panels 420 are sitting flush against an inner surface of respective pocket 424 such as in the illustration of FIG. 5. When the vehicle 400 is parked or stationary mode is otherwise engaged, an electric deployment motor (not shown) may cause solar panels 420 to deploy along the direction of arrow 402 from a position as integrated along frame 408 and substantially flush against pocket 424 to the deployed position. In other embodiments, the process of deploying solar panel 420 is a manual one, performed by a user turning a crank (not shown) or by the user simply lifting up the panel, e.g., using a tab on an external portion of solar panel 420 to pull the solar panel 420 out of pocket 424 and up into the deployed position.

FIG. 4A further shows additional features of vehicle 400 pursuant to an embodiment. Partially or fully transparent canopy 404 may be opened for passenger entry into vehicle 400. Vehicle 400 also contains windows 412 that may in certain embodiments be opened. In other embodiments, windows 412 constitute a part of canopy 404, and may open only with canopy 404. In other embodiments, windows 412 may be stationary in the closed position. A front wheel 410 includes wheel cover 414 and a rear wheel is closely arranged relative to frame 408. Vehicle 400 further includes front headlights 418 arranged in a small protrusion at the front of frame 408. It will be appreciated that the features of vehicle 400 are contoured so as to enable the vehicle 400 to be as aerodynamically biased as possible. The integration of solar panels 420 along the frame 408 in respective pockets 424 further reduces an aerodynamic drag on the vehicle 400 when the vehicle is in mobile mode.

FIG. 4B is a rear perspective view of a solar extended range electric vehicle 400 deploying its deployed solar panels from a position integrated along the frame. FIG. 4B shows the same features as FIG. 4A, except from a rear perspective view where taillights/brake lights 457 are visible. The back end 481 of the frame is contoured in this embodiment to enable continuous uninterrupted air flow when the vehicle 400 is moving. FIG. 4B also shows a portion of window 412, which may or may not be part of canopy 404.

FIG. 5 is a plan view of a solar extended range electric vehicle 400. FIG. 5 further illustrates that the wheels in this embodiment are closely coupled to the vehicle. FIG. 5 is a structurally distinct embodiment from the embodiment of FIGS. 4A and 4B in that a front of the vehicle has different features.

In an embodiment, the aerodynamic contour of the body as shown in the illustrations above assists not only in reducing the coefficient of drag overall, but also for enabling one of a dynamic leaning narrow track or a non-tilting wide track vehicle for turns.

The following portions of the specification discuss further benefits of the solar extended range electric vehicle, some of which were addressed in connection with FIGS. 1-5, above. These include:
1. Aerodynamic body for narrow track vehicle
2. Inline seating arrangement for aerodynamic body
3. Folding solar power arrays for high energy absorption and low drag on vehicles
4. Narrow track vehicles and suspension for dynamic leaning
5. Advantageous battery arrangements for solar vehicles

Enabling Practical Use of Solar Vehicles.

Personal transportation optimally uses minimal energy. However, transportation based entirely on solar electric power, which would result in very low vehicle energy consumption, is not presently feasible in passenger vehicles due to current practical limitations of solar panels. Thus, one solution as disclosed herein is to provide an electric vehicle which uses solar energy efficiently to extend overall range. In such an electric vehicle. the lowest energy consumption may result from minimizing mass (e.g., vehicle mass) and parasitic energy loss due to drag.

An electric vehicle with motor/generators may recover vehicle kinetic energy under braking. For example, a regenerative brake is an energy recovery mechanism which slows a vehicle or object by converting its kinetic energy into a form which can be either used immediately or stored until needed. A typical regenerative brake involves using an electric motor as an electric generator. Vehicles propelled by electric motors, such as the solar extended range electrical vehicle disclosed herein, use the motors as generators when using regenerative braking such that the act of braking can transfer mechanical energy from the wheels to electrical energy which in turn is used to power the vehicle. Thus, in an automated regenerative braking system, the vehicle's control system may automatically initiate battery charging when the brakes are applied. Regenerative braking systems consequently enable the vehicle to recover some of the associated kinetic energy loss.

The next major loss is aerodynamic drag which increases with the product of drag coefficient and frontal area. The drag coefficient is a dimensionless quantity that is used to quantify the drag or resistance of an object in a fluid environment, such as air or water. A lower drag coefficient generally indicates that the vehicle at issue has less aerodynamic drag. For example, the drag equation states:

$${F}_{D} = \frac{1}{2} ρ {v}^{2} {C}_{D} A$$

where
   F_{D} is the drag force, which is by definition the force component in the direction of the flow velocity,
   ρ is the mass density of the fluid,
   ν is the flow velocity relative to the object,
   A is the reference area, and
   C_{D} is the drag coefficient—a dimensionless coefficient related to the object's geometry and taking into account both skin friction and form drag.

From the above equation it is evident that the drag force F_{D} is proportional to the drag coefficient C_{D}, such that the drag force on the vehicle decreases with a lower C_{D}.

A fineness ratio of 3:1 or greater may be used to minimize the aerodynamic drag coefficient C_{D}. Fineness ratio is the ratio of the length of a body to its maximum width. This ratio can be used in the solar extended range electric vehicle to reduce drag, while simultaneously providing the passengers with a suitable environmental enclosure.

The frontal area is a function of the projected cross sectional area in the direction of travel. Upright passenger seating and visibility constraints increase roof height and consequently frontal area. Accordingly, to combat drag due to frontal area in an embodiment, vehicle width is minimized for lowest frontal area. Specifically, in one embodiment, inline passenger seating is used. Inline passenger seating increases a number of available seats without increasing frontal area. In other single-passenger embodiments, a single driver seat having a carefully controlled width may be provided.

In addition to the above considerations, the vehicle may include accommodation for static stability. Static stability is the ability of a body to remain upright when at rest, or under acceleration and deceleration. Static stability is a requirement that extends to fully enclosed passenger vehicles. One solution to achieving static stability is to provide a tricycle or quadricycle wheel system with the center of gravity located between the wheels both laterally and longitudinally. Narrow track vehicles with static stability will have reduced overturning moment due to the narrow track width. Dynamic leaning while cornering reduces overturning moment by aligning the inertial force vector with the center of the track. In an embodiment, a quadricycle wheel system 110 (FIG. 1) is employed. A quadricycle wheel system may advantageously permit torque-vectoring control in all modes (yaw+understeer+oversteer) as well as highest overturning moment for best vehicle dynamics. In another embodiment, a three wheel system may be used.

In an embodiment, inline seating 104 (FIG. 1) coupled with handlebar steering controls 126 (FIG. 3D) common to single track vehicles such as motorcycles is implemented in the solar extended range electric vehicle. Steering control for dynamic leaning vehicles uses gyroscopic precession and is a function of lean angle and steer torque. As such, driver path determination using means other than through steer angle and controls, such as with a steering wheel, may be more complex. However, other embodiments including a steering wheel, such as when maneuvering demands or the vehicle's base configuration is different, are possible.

In another embodiment, the vehicle may use straddle seating with foot controls minimized. For example, one or more functions ordinarily controlled using foot controls may be instead controlled using alternative hand-accessible controls. Alternatively or in addition, a size of the foot controls may be minimized and more spread out among the available area proximate the driver's foot position. The minimization of foot controls may advantageously allow battery placement of battery cells 122 (FIG. 1) under the passengers, such as toward a center or near edges of the exterior structure 112. In this embodiment, primary structural load paths may be provided along the surface of the battery cells 122. A central backbone structure (described further below) may be coupled to or arranged on the exterior structure 112 and the backbone structure may provide mounting points for the suspension system 116. In an embodiment, the backbone structure may include or incorporate the electrical high voltage power system. This chassis structure arrangement as described with respect to this embodiment may be best suited to low frontal area aerodynamic vehicles and, as a result, may impose the least resistance and the lowest losses due to frontal area for the vehicle.

In an embodiment, as shown in FIGS. 2A-D, 3A-D, 4A-B and 5, stowable solar power arrays 106, 108, 420 may provide maximum energy absorption while simultaneously minimizing aerodynamic drag by folding flush along the frame while the vehicle is mobile. This configuration yields an effective solar range extended vehicle architecture.

While the above-described configuration yields a vehicle architecture consistent with the present disclosure, it will be appreciated that numerous modifications to the vehicle may be made while preserving its energy efficient, drag-resistant nature. As such, the configurations and embodiments described above are exemplary in nature and are not intended to limit the scope of the present invention to these particular embodiments.

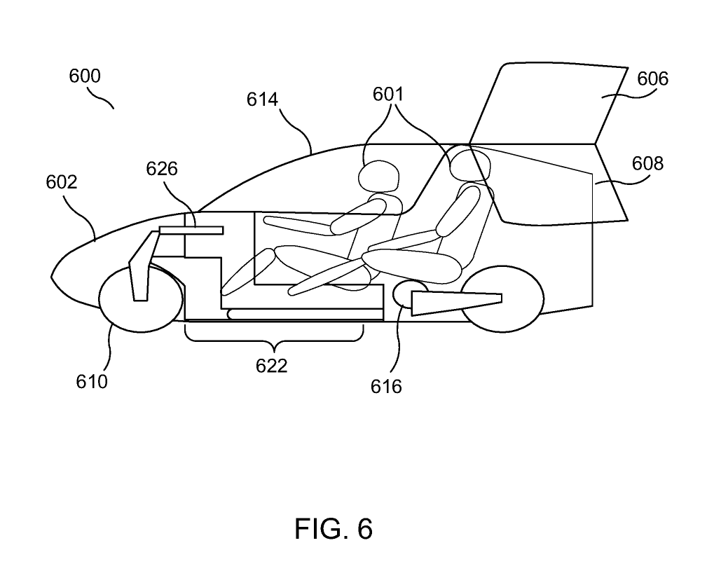

FIG. 6 is a side view showing an exemplary relative placement of passengers using inline seating and certain other structures in a solar extended range electric vehicle 600. FIG. 6 is similar to previous embodiments and shows two occupants 601 arranged in a dual inline seating configuration, an aerodynamic body 602 in which frontal surface area and drag coefficient are minimized as discussed above, a battery assembly 622 including a collection of battery cells arranged below the occupants that may create a primary load path along a surface of the battery cells. A solar array including two panels 606 (one shown) engaged to receive more solar energy when the sun is higher and two panels 608 (one shown) engaged to receive more solar energy when the sun is lower and angled relative to the vehicle 600 are illustrated. Further shown in FIG. 6 are handlebars 626 for effecting steering and a wheel system 610 including four wheels coupled to a suspension system 616. The front nose of the vehicle 600 may in some embodiments be configured to include space for two to four storage bags, e.g., from a grocery store.

Aerodynamic Body for Narrow Track Vehicle.

A fundamentally low aerodynamic drag shape will minimize pressure drag and form (i.e., friction) drag simultaneously. Pressure drag may be minimized through the use of gradual transitions in cross-section such that the volume of fluid displaced per increment of vehicle length is lowest. This gradual cross-section change is called ‘area-ruling’, which in three dimensions may be most similar to two cones placed base-to-base and whose axes align with the path of the shape.

Gradients between areas of dynamic and static pressure should ideally result in a rate of change of area to be gradual, smoothing the exterior profile from angled lines to a curve. Where negative gradients occur, an ideal shape may be a shallow exponential curve body of revolution, typically from the maximum cross-section to the trailing edge. Lastly, relative motion between solids and fluids causes friction (at low speeds friction is much lower than pressure drag), and the lowest surface area to volume ratio for a given design may have the lowest friction—which is why the leading edge approaches a spherical cross-section. All of the above describe the ideal ‘teardrop’ aerodynamic shape from a physics perspective (see, e.g., FIG. 5). The inventor has found that experimental data for 2-D shapes describe a 3:1 length to thickness that may provide the lowest coefficient of drag.

Applicability to surface vehicles is embodied by a teardrop shape in planform. Passengers are most comfortable with torsos generally upright, and seated frontal area is generally shoulder width versus trunk and head height—or a 2:1 height to width ratio. Such a vehicle will also preferably have more vertical cross-section behind the rear wheels which puts the center of pressure behind the center of gravity for improved yaw stability. For lowest drag, the suspension and wheels may be submerged in the bodywork, which is substantially the case with at least the embodiments shown in FIGS. 1-6.

Inline Seating Arrangement for Aerodynamic Body.

As noted above, single track vehicles generally provide an inline seating arrangement for passengers. These vehicles are low mass and low cost, but generally have no environmental exposure control nor impact protection.

In contrast to these conventional single-track vehicles, a narrow-track vehicle may, in another aspect of the present disclosure, be configured to monopolize on the low frontal area provided by inline seating, while simultaneously providing structure for environmental exposure control and impact protection. The vehicle may include packaging volume for high voltage batteries for energy storage which, as in prior embodiments, can be located beneath the passengers if the seating is generally recumbent and fore and/or aft of the passenger compartment.

In another aspect of the disclosure, the vehicles described above may be assembled via a frame comprised of a plurality of nodes, or 3-D printed joints that connect structural components such as, for example, carbon fiber connecting tubes, to form the vehicle chassis. Furthermore, in an embodiment, the deployment mechanism of the solar panels may be achieved by the use of additive manufacturing. In other embodiments, additively manufactured parts would be combined with other custom machined parts or with commercial-off-the-shelf (COTS) part to produce the final vehicle.

Folding Solar Power Arrays for High Energy Absorption and Low Drag on Vehicles.

Adequate solar energy absorption for a solar powered vehicle to achieve range targets implies large surface area of solar conversion cells. Most solar powered vehicles achieve the necessary surface area by implementing the largest possible plan area of the vehicle and installing solar cells on every available surface. However, these conventional approaches can be problematic and unpredictable. For example, many of these cells are inefficient as they provide low cross-section to the emitter during charging as the solar emitter moves across the sky, thereby driving further cost and mass into the vehicle to increase surface area for more paneling and achieve necessary energy absorption. Secondarily, the frontal area of the vehicle increases with width in plan view.

Planar arrays are the simplest implementation to achieving a given cross-section for a lowest mass, but other mostly planar arrangements may perform nearly as well from a specific mass per unit energy basis. Conformal arrays are possible, but require flexible cells and when deployed yield lower solar power due to cosine losses. Similarly, painted-on cells can yield larger surfaces, but also suffer from cosine losses. Telescoping planar arrays also improve solar absorption by increasing available surface area. Lastly, multi-hinged panels can be implemented—but likely with highest mass.

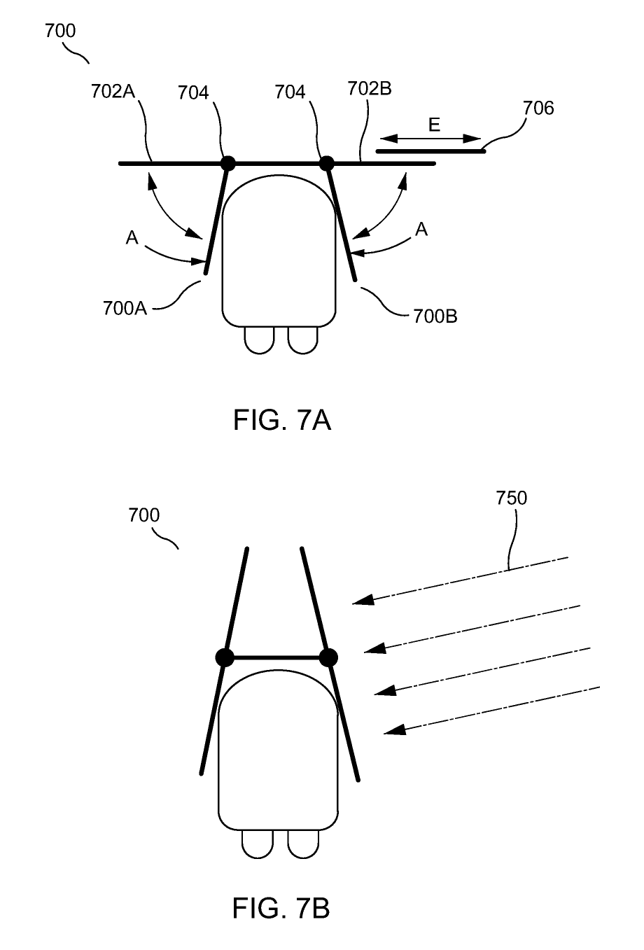

FIG. 7A is a conceptual elevation view 700 of solar extended range electric vehicle 700 having deployable solar arrays 702A-B. Deployable solar arrays 702A-B may increase cross-sectional area in a position normal to the solar emitter (in plan or elevation view), and may further allow overall vehicle cross-section to remain small in the frontal area when the deployed solar arrays are stowed for low aerodynamic drag as previously described. In an embodiment, some solar arrays may be emitter-tracking for increased performance. However, emitter-tracking solar arrays may add some complexity, cost and mass relative to single axis tracking with a value proposition of 10-20% increased performance. For this embodiment, that value should be first assessed in view of the added complexity.

Referring still to FIG. 7A, simple planar arrays with a single pivot 704 may allow an array to deploy and change available cross-section normal to the pivot axis. Functionally, the array size will then be limited by the planar cross-section available in elevation (side) view, especially for narrow-track vehicles. Another deployable array 702A-B nests at least two planar panels with near co-axial stowing pivot axes, such that the deployed surface area A for solar absorption is a multiple of available elevation planar cross-section. Telescopic extension E of stowed panels 706 may also enhance available area.

FIG. 7B is a conceptual elevation view of solar extended range electric vehicle 700 engaged in active tracking of solar radiation 750. Software-controlled active tracking of solar radiation in both elevation height and azimuth angle can maximally capture solar power when the sun is low on the horizon, with increased insolation area as compared to a single panel (assuming pivot axis is perpendicular to latitude lines). Mid-day the upper panels would actively track the sun in two axes for increased effective panel area.

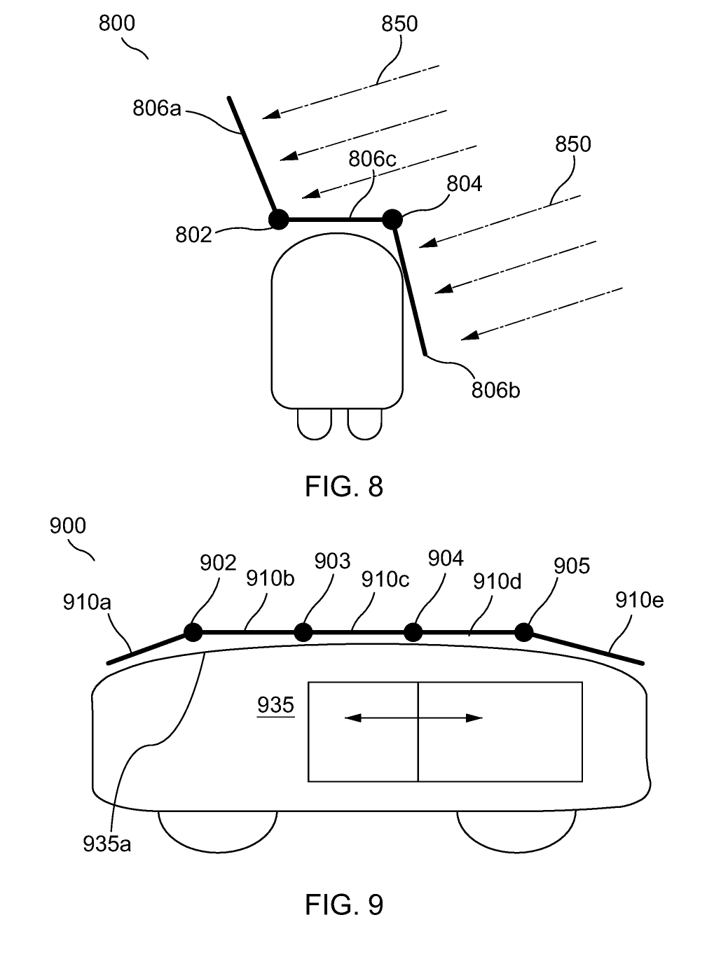

In another embodiment, the solar arrays on a vehicle, using active tracking or manual deployment techniques, can be optimized for most efficient capture of the sun's rays, subject to the capabilities of the configuration of the solar array. FIG. 8 is a conceptual elevation view of the solar extended range electric vehicle 800. Recognizing that the radiation is coming from the left of the vehicle, the vehicle accordingly configures the position of solar panels 806A and 806B about its respective pivots 802 and 804 until the solar radiation is substantially orthogonal to a plane of solar panels 806A-B. Concurrent with the exposure of these panels, solar panel 806C is receiving solar radiation, albeit at an angle, but which cumulatively affects the amount of energy stored in the battery cells of vehicle 800. When vehicle 800 is prepared to go into its mobile mode, it may move solar panel 806A (and if necessary, solar panel 806B)) for secure and flush placement along a frame of the vehicle.

In another embodiment, the arrays of solar panels may be configured to form a canopy over the vehicle for maximum exposure. FIG. 9 is a conceptual side view of a solar extended range electric vehicle 900 deploying an array of five panels 910A-E coupled together by respective pivots 902-905 and extending across a surface 935A of its frame 935. In one embodiment, to enable this configuration, solar panels 910A-E may be stored under the hood panel and may be deployed when the vehicle 900 is in stationary mode.

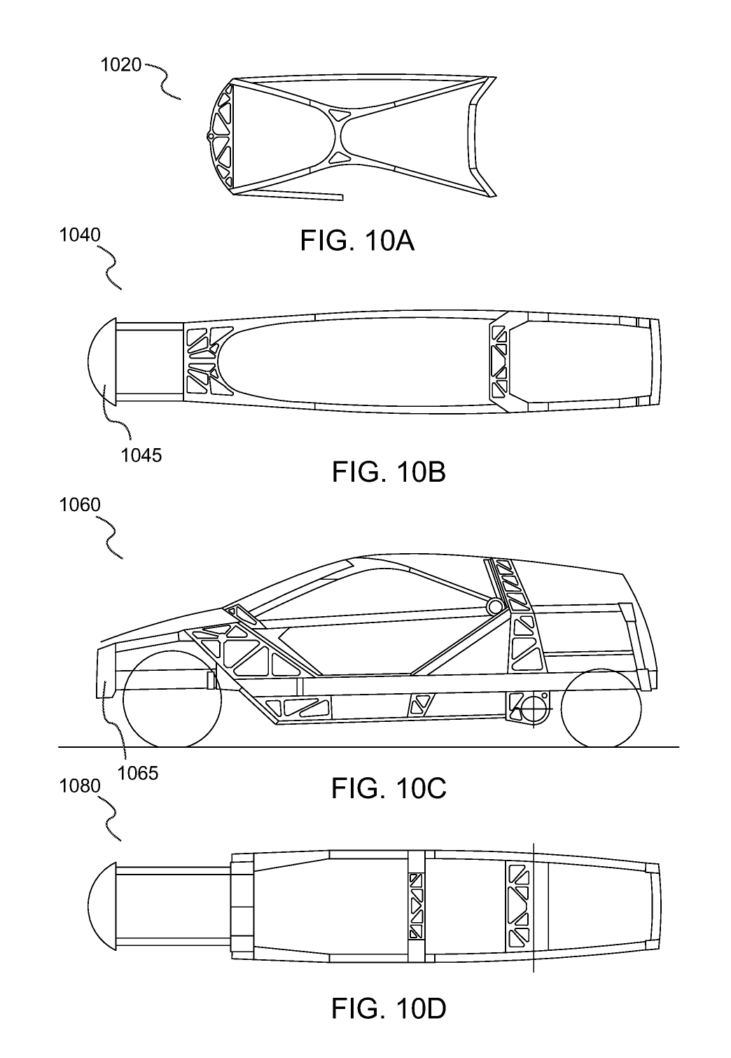

In another embodiment discussed below with reference to FIGS. 10A-12, a composite tub structure creates a sealed compartment and supplements the alloy space frame or chassis structure. The metal chassis structure or the exterior structure is coupled to the composite tub structure to thereby secure the composite tub structure.

The solar extended range electric vehicle is, in one embodiment, composed of several smaller structures designed not only to impart small mass and aerodynamic features to the vehicle but also to protect it occupants from injury in an impact event. FIG. 10A is a plan view of a canopy frame 1020 designed for use as an upper part of the exterior structure and configured to be suspended over the head of the occupants for protection against accidents and instances where the vehicle loses control. In an embodiment, the canopy frame is additively manufactured.

FIG. 10B is a plan view of an exterior structure 1040. The exterior structure may, in one embodiment, be secured to a floor of the chassis or space frame. Alternatively, the exterior structure may form part of the space frame and may span a perimeter of the space frame. The exterior structure may also be coupled to an impact structure 1045 arranged in front of the frame. This is shown in FIG. 10C, which is a plan view of a vehicle frame 1060 and the exterior structure 1040 mounted in the frame with an impact structure 1065 arranged in front of the frame. The exterior structure may be additively manufactured in an embodiment. An underside of the exterior structure 1080 is depicted in FIG. 10D. One or more of these components, including the canopy frame 1020 and the exterior structure 1040 or 1080, maybe 3-D printed, or they may be extruded in part or in whole. In another embodiment, the exterior structure 1040, 1080 is mounted or otherwise attached to the alloy space frame (FIG. 10C) and serves as a floor or base of the vehicle or as a reinforcement to the perimeter of the alloy space frame. In another embodiment, other components of the vehicle may be mounted to the exterior structure shown in FIGS. 10B-D. For example, the suspension system or wheel system or both may be mounted to the exterior structure and, in other embodiments, the alloy space frame. In some embodiments, the suspension system is mounted to both the alloy space frame and the exterior structure. In still other embodiments, the suspension system may be mounted to just the alloy space frame. The canopy frame 1020, exterior structure 1040 and 1080 and alloy space frame 1060 with (and in some cases, without) interior tub 1100 (below) serve to provide a protectable shell for the vehicle and occupants and to enable mounting of other critical systems thereto so that the vehicle has the necessary structural integrity.

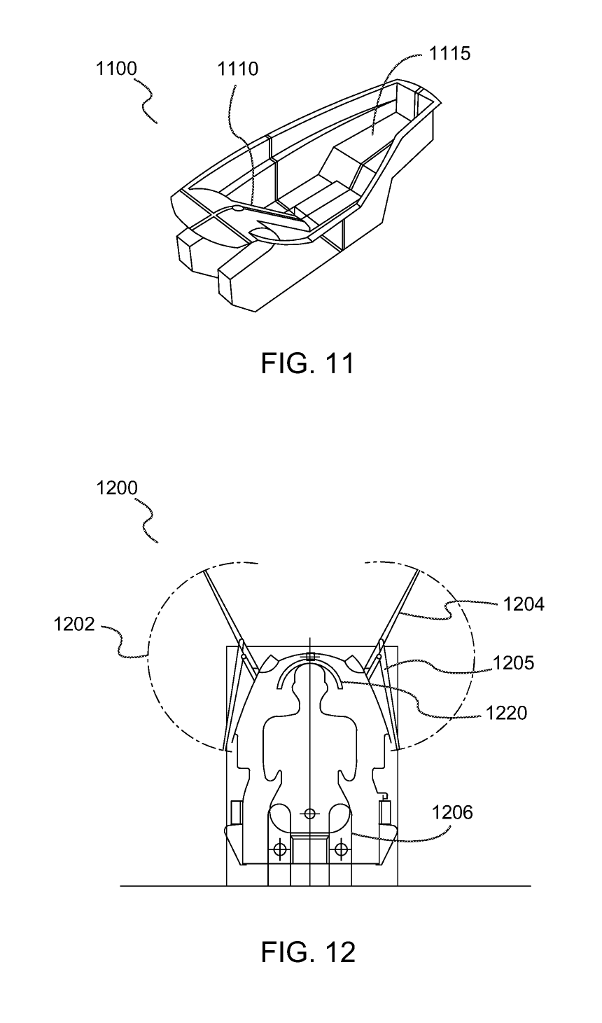

In another embodiment, an interior tub 1100 is provided for use within the alloy space frame. FIG. 11 is a perspective view of a composite interior tub 1100 for use in the space frame structure (chassis) 1060 of the solar extended range electric vehicle. In one embodiment, interior tub is made from a composite material, such as carbon fiber reinforced polymer (CFRP), glass reinforced polymer (GRP) or another suitable composite. In one embodiment, interior tub includes an interior that has a seat shaped contour 1110 and feet room 1115 for accommodating an occupant. Interior tub may be molded, additively manufactured, or produced using any acceptable fabrication process.

In an embodiment, interior tub 1100 is located within the alloy space frame. The space frame may be mounted directly to the tub, or the exterior structure (FIG. 10B-D) may be mounted to the tub, or both the space frame structure and the exterior structure may be mounted to the tub. This eliminates the need for mass and volume-adding body fixtures to attach the interior tub 1100 to the vehicle. The metal structure mounted to the tub may include additively-manufactured components as well as extruded components.

The interior tub 1100 may effectively create a sealed interior compartment for an occupant within the vehicle, adding an extra layer of protection for the occupant in an impact event. With the interior tub 1100 structurally mounted in a solid way in the frame or exterior structure of the vehicle, a single integrated component may be created that can protect the driver in the event of a collision or other significant forces exerted on the vehicle. In another embodiment, an interior tub may be created and designed to withstand two occupants in the vehicle. Alternatively, the vehicle may include a second interior tub situated inline with the first interior tub. This embodiment may result, however, in excessively large profiles. In another embodiment, the interior tub is extended and additional seating structure is provided so that it can accommodate more than one occupant or object.

In the embodiment where the interior tub 1100 is composed of a composite material such as carbon fiber, the interior tub 1100 may be made significantly lighter than, e.g., an all metal component. This light construction contributes to the overall mass savings of the solar vehicle. The interior tub 1100 may also protect the occupant from exposure to the battery cells beneath the user. The interior tub 1100 may also be personalized or stylized to the desire of the occupant and may easily be configured to receive wiring routed from other parts of the vehicle to power on one or more subsystems.

FIG. 12 is a rear transparent view of the solar extended range electric vehicle 1200 in which an occupant is seated within the composite tub of FIG. 11. The solar extended range electric vehicle is a referred to as narrow track vehicle and, as shown, the vehicle is in the stationary mode with panels 1204 deployed. Also deployed at a wider and lower angle are solar panels 1205. Semi-circles 1202 are not part of the vehicle 1200, but rather represent physical range of panels 1204 when extended. A portion of canopy frame 1520 can be seen above the occupant protecting the occupant's head.

Tires 1206 are in close proximity to one another in this narrow track embodiment. In other embodiments, such as in wide track vehicles or similar, the wheels are father spread apart. Interior tub 1600 from FIG. 16 is seen as integrated in this embodiment into the frame and exterior structure.

Various packaging options have been considered in an attempt to increase the total surface area of the solar panels, based on certain configurations of the panels. The increases in surface areas generally translate to an increased solar absorption and consequently an increased storage of electricity based on that absorption. However, this increase is beneficial only to a point where the increased area and configuration of the solar panels provide further benefit to increase the overall range of the vehicle. Stated differently, there is a point beyond which the car will not experience any appreciable gains from a larger solar area. Some viable options for the surface areas are identified below.

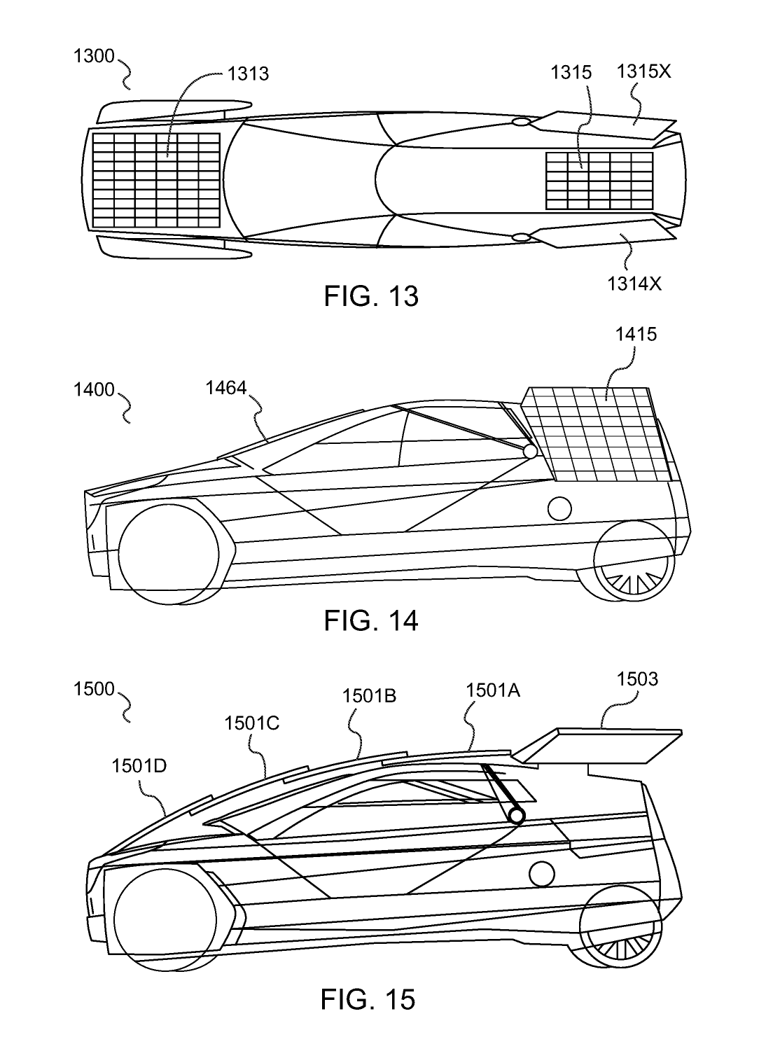

FIG. 13 is a plan view of a solar extended range electric vehicle 1300 having solar panels arranged in an exemplary configuration along a front and a rear of the frame. Arranged along a rear region of the frame of vehicle 1300 is a first panel 1315 that is static, i.e., it does not move. In addition to panel 1315, two side panels 1315x and 1314x can be seen disposed on the sides of the rear frame adjacent horizontal component 1315. The combination of these three solar panels 1315, 1315x and 1314x yields a surface area of 400 cm².

In a front region of vehicle 1300, solar panel 1313 is arranged in an evidently static pattern of the frame along a front region is solar panel 1313, which measures a considerably larger 600 cm². Thus the total surface area of panels exposed to sunlight=600 cm²+400 cm²=1000 cm².

FIG. 14 is a side view of a solar extended range electric vehicle 1400 having solar panels arranged in another exemplary configuration along a rear of the frame. The vehicle 1400 differs from that of FIG. 13 in that the solar panels 1415 are in the rear only. There are, however, a total of two panels 1415, each having a surface area of 600 cm². Therefore, the total surface area of the array is 1200 cm² or 200 cm² greater than the vehicle of FIG. 13. It should also be noted that, unlike the two of the four solar panels in FIG. 13, the two panels 1415 in FIG. 14 are both movable from their integration areas along the frame. It is also noteworthy that the vehicle 1400 lacks the lower displaced panels that are otherwise beneficial to capture solar energy when the sun is low on the horizon in the evening. However, in addition to the solar panel array 1415 on the vehicle 1400 of FIG. 14, another solar panel 1464 extends down the front center of the canopy. This panel 1464 may in one embodiment be manually placed in position, or in another embodiment it may be configured to automatedly telescope from the hood area into its position. The total surface area of the solar panels of the vehicle in FIG. 14 is 2.2 m².

FIG. 15 is a side view of a solar extended range electric vehicle 1500 having foldable solar panels arranged along a top surface of the frame in a foldable manner in still another exemplary configuration. In addition to the solar array of panels 1503 arranged along the rear portion along the sides of the frame, an array 1501A-D extends down the center of the frame. Thus, in this embodiment, the solar array is configured to form a canopy over the vehicle for maximum exposure.

To enable the configuration of FIG. 15, solar panels may be stored under the hood panel and may be deployed. Thus, in one embodiment, the solar panels begin at panel 1501D, atop the hood of vehicle 1500, and begin to deploy by each solar panel 1501 sliding forward until it stops moving due to a trapper mechanism under the hood.

In addition, a deployment motor (not shown) may cause the solar panels 1501A-D to slide to the right (relative to FIG. 15) and to open in sequence. For example, the solar panel 1501A at the bottom of the stack may start to slide first and then may stop when it has reached its end of solar panel 1501B, at which point solar panel 1501A pulls out solar panel 1501B which in turn slides and pulls out solar panel 1501C, and so on until all panels 1501A-D are deployed. In addition, a separate deployment motor may cause solar panel 1503, and its counterpart on the other side of the vehicle, to be deployed. The total surface area from all these deployed canopy panels is 3.7 m².

The previous description is provided to enable any person skilled in the art to practice the various aspects described herein. Various modifications to the exemplary embodiments presented throughout this disclosure will be readily apparent to those skilled in the art, and the concepts disclosed herein may be applied to other solar vehicles and for techniques for additively manufacturing structures within solar vehicles. Thus, the claims are not intended to be limited to the exemplary embodiments presented throughout the disclosure, but are to be accorded the full scope consistent with the language claims. All structural and functional equivalents to the elements of the exemplary embodiments described throughout this disclosure that are known or later come to be known to those of ordinary skill in the art are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f), or analogous law in applicable jurisdictions, unless the element is expressly recited using the phrase “means for” or, in the case of a method claim, the element is recited using the phrase “step for.”

1. A solar extended-range vehicle, comprising:
a frame coupled to an exterior structure;
a suspension system mounted to the exterior structure and coupled to a wheel system;
at least one electric motor coupled to the wheel system; and
at least one stowable solar electric panel arranged along a region of the frame for supplying power to the electric motor.

2. The vehicle of claim 1, wherein the at least one solar electric panel is integrated into the frame.

3. The vehicle of claim 1, wherein the at least one solar electric panel is automatedly deployable to an open position.

4. The vehicle of claim 1, wherein the at least one solar electric panel is arranged along the exterior structure.

5. The vehicle of claim 1, further comprising a battery assembly for storing electric charge received from the at least one solar electric panel.

6. The vehicle of claim 5, wherein the battery assembly is arranged within a center area of the exterior structure near a front of the frame.

7. The vehicle of claim 1, further comprising a backbone structure disposed along a periphery of the exterior structure near a front of the frame.

8. The vehicle of claim 7, wherein the backbone structure further comprises an electrical power system.

9. The vehicle of claim 7, wherein the battery assembly is integrated within a center area of the backbone structure.

10. The vehicle of claim 1, further comprising an impact structure arranged within the frame near a front of the frame.

11. The vehicle of claim 10, further comprising a structure linked to the impact structure for transferring loads from the impact structure to a base of the exterior structure.

12. The vehicle of claim 11, further comprising a backbone structure disposed along a periphery of the exterior structure and operably coupled to the suspension system.

13. The vehicle of claim 1, further comprising inline seating arranged within the frame along a base of the exterior structure.

14. The vehicle of claim 1, wherein the wheel system comprises a quadricycle wheel system.

15. The vehicle of claim 1, further comprising an interior tub structure mounted to a base of the exterior structure and configured to create a substantially sealed interior compartment.

16. The vehicle of claim 1, further comprising handlebar steering controls coupled to the suspension and wheel systems and configured to facilitate dynamic leaning during turns.

17. The vehicle of claim 1, wherein the frame comprises one or more additively manufactured panels.

18. The vehicle of claim 1, wherein at least a portion of the exterior structure is additively manufactured.

19. The vehicle of claim 1, wherein an interior of the frame comprises a plurality of additively manufactured interconnected nodes.

20. The vehicle of claim 1, wherein the one or more stowable solar panels are configured to fold substantially flush with the frame.

21. A solar extended range electric vehicle, comprising:
a frame coupled to an exterior structure;
a suspension system mounted on the exterior structure;
an impact structure arranged near a front of the frame and coupled to the suspension system;
a wheel system coupled to the suspension system;
a plurality of electric motors operably coupled to the wheel system; and
at least one stowable solar panel operably coupled to a battery assembly.

22. The vehicle of claim 21, wherein the at least one solar panel is arranged along an exterior of the frame.

23. The vehicle of claim 21, wherein the plurality of electric motors further comprise wheel motors configured to provide mechanical power to at least two wheels of the wheel system.

24. The vehicle of claim 21 further comprising a structure disposed along a periphery of a base of the exterior structure for housing the battery assembly.

25. The vehicle of claim 21, wherein the suspension system is coupled to the impact structure via the exterior structure.

26. The vehicle of claim 21, wherein a canopy frame is suspended from an upper portion of the frame along a periphery of the frame.

27. The vehicle of claim 21, wherein the frame comprises one or more additively manufactured panels.

28. The vehicle of claim 21, wherein at least a portion of the exterior structure is additively manufactured.

29. The vehicle of claim 21, wherein an interior of the frame comprises a plurality of additively manufactured interconnected nodes.

30. The vehicle of claim 21, wherein the at least one stowable solar electric panel is automatedly deployable to an open position.
